(19) United States
(12) Patent Application Publication
(10) Pub. No.: US 2015/0270421 A1
(43) Pub. Date: Sep. 24, 2015

(54) Advanced Back Contact Solar Cells

(71) Applicant: Varian Semiconductor Equipment Associates, Inc., Gloucester, MA (US)

(72) Inventors: Min-Sung Jeon, Jeonju-City (KR); Bon-Woong Koo, Andover, MA (US)

(21) Appl. No.: 14/220,560

(22) Filed: Mar. 20, 2014

(51) Int. Cl. H01L 31/0224; H01L 31/0376; H01L 31/18; H01L 31/0216

(52) U.S. Cl. CPC H01L 31/022441; H01L 31/02168; H01L 31/03762; H01L 31/1864

(57) ABSTRACT

An improved method of manufacturing a back contact solar cell is disclosed. The method is particularly beneficial to the creation of interdigitated back contact (IBC) solar cells. A mask paste is applied to the tunnel oxide layer. Silicon is deposited on the tunnel oxide layer. The placement of the mask paste causes discrete regions of deposited silicon to be created. Using a shadow mask, dopant is implanted into one or more of these discrete and separate regions. After the implanting of dopant, metal is sputtered onto the deposited silicon to create electrodes. Following the deposition of the metal layer, the mask paste is removed, such as using a wet etch process. The resulting solar cell has discrete doped regions each with a corresponding electrode applied thereon. These discrete doped regions are separated by a gap, which extends to the tunnel oxide layer.

### FIELD

This disclosure relates to solar cells and, more particularly, to back contact solar cells formed using ion implantation.

### BACKGROUND

Ion implantation is a standard technique for introducing conductivity-altering impurities into a workpiece. A desired impurity material is ionized in an ion source, the ions are accelerated to form an ion beam of prescribed energy, and the ion beam is directed at the surface of the workpiece. The energetic ions in the beam penetrate into the bulk of the workpiece material and are embedded into the crystalline lattice of the workpiece material to form a region of desired conductivity.

Solar cells are one example of a device that uses silicon workpieces. Any reduced cost to the manufacture or production of high-performance solar cells or any efficiency improvement to high-performance solar cells would have a positive impact on the implementation of solar cells worldwide. This will enable the wider availability of this clean energy technology.

In some embodiments, the front surface of the solar cell includes a doped front surface field (FSF), covered by an anti-reflective coating (ARC). The back surface may include a pattern of doped emitters and doped back surface fields (BSF), where metal electrodes are connected to these emitters and BSFs. This configuration allows the entire front surface to be exposed to the solar energy, as no electrodes are disposed on the front surface, blocking the light energy.

However, the configuration requires two differently doped regions on the back surface, along with the corresponding electrodes. This may make manufacturing of the solar cell difficult. Thus, any method that simplifies the manufacture of these back contact solar cells would be beneficial.

### SUMMARY

An improved method of manufacturing a back contact solar cell is disclosed. The method is particularly beneficial to the creation of interdigitated back contact (IBC) solar cells. A mask paste is applied to the tunnel oxide layer. Silicon is deposited on the tunnel oxide layer. The placement of the mask paste causes discrete regions of deposited silicon to be created. Using a shadow mask, dopant is implanted into one or more of these discrete and separate regions. After the implanting of dopant, metal is sputtered onto the deposited silicon to create electrodes. Following the deposition of the metal layer, the mask paste is removed, such as using a wet etch process. The resulting solar cell has discrete doped regions each with a corresponding electrode applied thereon. These discrete doped regions are separated by a gap, which extends to the tunnel oxide layer.

According to one embodiment, a method of creating a back contact solar cell using a substrate is disclosed. The method comprises depositing a tunnel oxide layer to a surface of the substrate, where the tunnel oxide covers an entirety of the surface; applying a mask paste to the tunnel oxide layer; depositing a silicon layer onto the tunnel oxide layer, where the mask paste prevents silicon from being deposited on a portion of the tunnel oxide layer and wherein the mask paste separates the silicon layer into a plurality of discrete regions; doping each of the plurality of discrete regions, so as to create emitter regions and back surface field regions; performing a thermal process to anneal the emitter regions and back surface field regions; applying a metal layer on top of the emitter regions and the back surface field regions after the thermal process; and removing the mask paste after the applying of the metal layer.

According to another embodiment, a method of creating a back contact solar cell using a substrate is disclosed. The method comprises depositing a tunnel oxide layer to a surface of the substrate, where the tunnel oxide covers an entirety of the surface; applying a mask paste to the tunnel oxide layer; depositing silicon and a first dopant onto the tunnel oxide layer to form a doped silicon layer, where the mask paste prevents silicon and the first dopant from being deposited on a portion of the tunnel oxide layer and wherein the mask paste separates the doped silicon layer into a plurality of discrete regions, wherein each of the discrete regions is already doped; doping a subset of the plurality of discrete regions, with a second dopant, having a conductivity opposite the first dopant, sufficient to change the conductivity of the subset, to create emitter regions and back surface field regions; performing a thermal process to anneal the emitter regions and back surface field regions; applying a metal layer on top of the emitter regions and the back surface field regions after the thermal process; and removing the mask paste after the applying of the metal layer.

According to a third embodiment, a back contact solar cell is disclosed. The back surface solar cell comprises a substrate having a front surface and a back surface; a tunnel oxide layer disposed on the back surface; and a plurality of discrete regions disposed on the tunnel oxide layer, each discrete region comprising: a doped silicon layer disposed on the tunnel oxide layer; and a metal layer disposed on the doped silicon layer; wherein each of the discrete regions is separated from an adjacent discrete region by a gap. In a further embodiment, the gap extends from the metal layer to the tunnel oxide layer. In another further embodiment, the metal layer covers an entirety of the doped silicon layer. In a further embodiment, a first subset of the plurality of the discrete regions comprises p-type doped emitter regions and a second subset of the plurality of discrete regions comprises n-type doped back surface field regions.

### BRIEF DESCRIPTION OF THE DRAWINGS

For a better understanding of the present disclosure, reference is made to the accompanying drawings, which are incorporated herein by reference and in which:

FIG. 1 is a cross-sectional view of back contact solar cell according to the prior art;

FIG. 2 is a bottom view of the back contact solar cell of FIG. 1;

FIGS. 3A-I are cross-sectional views of a first method to form a back contact solar cell;

FIGS. 4A-H are cross-sectional views of a second method to form a back contact solar cell;

FIG. 5A is a cross-sectional view of the back contact solar cell made according to the method of FIGS. 3A-I; and

FIG. 5B is a cross-sectional view of the back contact solar cell made according to the method of FIGS. 4A-H.

### DETAILED DESCRIPTION

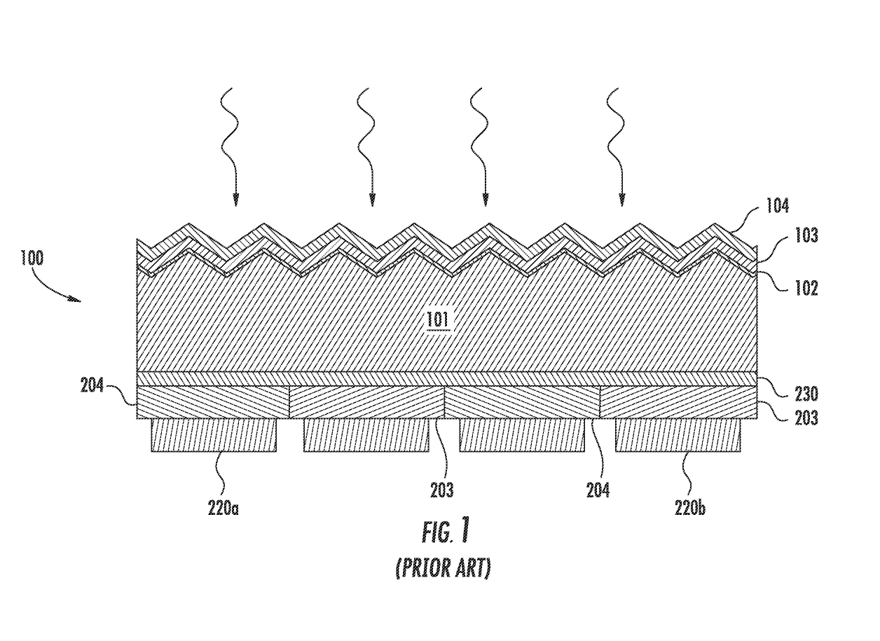

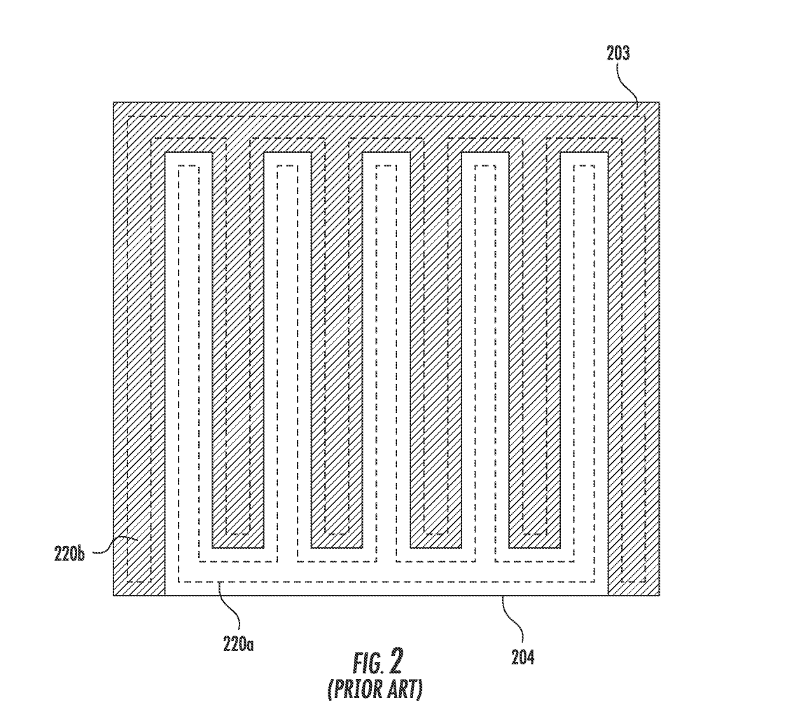

Solar cells typically include a p-n semiconducting junction. FIG. 1 is a cross-sectional view of a typical back contact solar cell. In a back contact solar cell, the p-n junction is on the back or non-illuminated surface of the solar cell. Photons enter the solar cell 100 through the top (or illuminated) surface, as signified by the arrows. These photons pass through an anti-reflective coating (ARC) 104, designed to maximize the number of photons that penetrate the solar cell 100 and minimize those that are reflected away from the substrate. The ARC may be comprised of an SiNₓ layer. Beneath the ARC 104 may be a SiO₂ layer, also known as a passivation layer 103. Of course, other dielectrics may be used. On the back side of the solar cell 100 is an emitter region 203.

Internally, the solar cell 100 is formed so as to have a p-n junction. This junction is shown as being substantially parallel to the top surface of the solar cell 100, although there are other implementations where the junction may not be parallel to the surface. In some embodiments, the solar cell 100 is fabricated using an n-type substrate 101. The photons enter the solar cell 100 through the n+ doped region, also known as the front surface field (FSF) 102. The photons with sufficient energy (above the bandgap of the semiconductor) are able to promote an electron within the semiconductor material's valence band to the conduction band. Associated with this free electron is a corresponding positively charged hole in the valence band. In order to generate a photocurrent that can drive an external load, these electron hole (e-h) pairs need to be separated. This is done through the built-in electric field at the p-n junction. Additionally, a tunnel oxide layer 230 is disposed between the bulk material of the n-type substrate and the p-doped emitter region 203 and the n-doped back surface field regions 204. The tunnel oxide layer 230 may reduce the created carriers' surface recombination velocity on the surface of p-doped emitter and n-doped BSF, and may also reduce or prevent the flow of majority carriers toward the p-doped emitter region 203. Thus, any e-h pairs that are generated in the depletion region of the p-n junction get separated, as are any other minority carriers that diffuse to the depletion region of the device. Since a majority of the incident photons are absorbed in near surface regions of the device, the minority carriers generated in the emitter need to diffuse to the depletion region and get swept across to the other side.

As a result of the charge separation caused by the presence of this p-n junction, the extra carriers (electrons and holes) generated by the photons can then be used to drive an external load to complete the circuit.

The doping pattern is alternating p-type and n-type dopant regions in this particular embodiment. The n+ back surface field 204 may be between approximately 0.1-0.7 mm in width and doped with phosphorus or other n-type dopants. The p+ emitter region 203 may be between approximately 0.5-3 mm in width and doped with boron or other p-type dopants. This doping may enable the p-n junction in the IBC solar cell to function or have increased efficiency.

FIG. 2 shows a pattern which may be used for the back side of the back contact solar cell of FIG. 1. This configuration may be referred to as an interdigitated back contact (IBC) solar cell. The metallic contacts or fingers 220 are all located on the bottom surface of the solar cell 100. Certain portions of the bottom surface may be implanted with p-type dopants to create emitter regions 203. Other portions are implanted with n-type dopants to create more negatively biased back surface field (BSF) 204. Metal fingers 220b are attached to the emitter region 203 and metal fingers 220a are attached to the BSF region 204.

The creation of differently doped regions, which are disposed adjacent to one another, requires careful alignment of the implantation or doping process, as well as the metallization process.

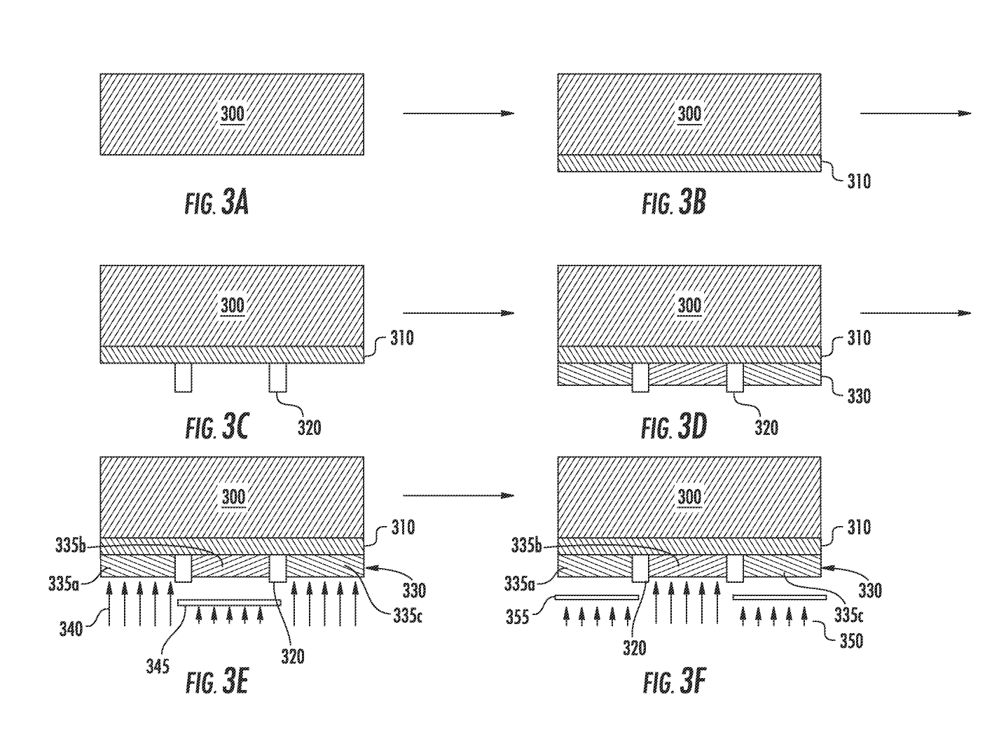

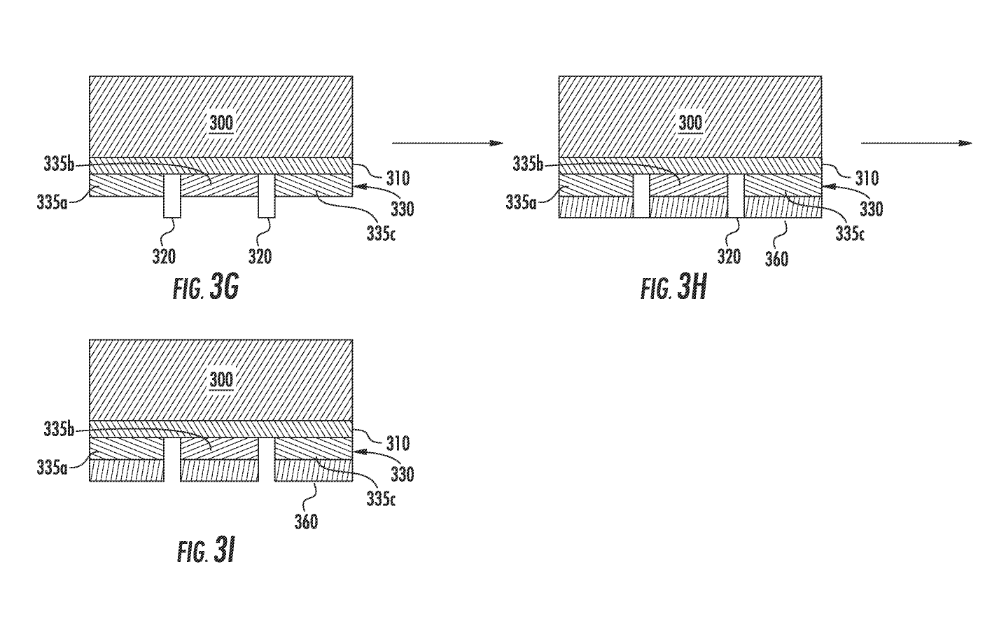

FIGS. 3A-3I show a manufacturing process to create a back contact solar cell according to a first embodiment. In FIG. 3, pyramid shape on the top surface of the substrate, shown in FIG. 1 is omitted for simplicity. An n-type substrate 300 is used to create the desired solar cell. Although not shown, the front surface of the substrate 300 may be implanted or otherwise doped with n-type dopant to create a more heavily n-doped front surface field (FSF). The front surface of the solar cell may also be coated with a passivation layer and an anti-reflective coating, which may be deposited on the FSF or on the bulk substrate 300. In addition, the front surface of the substrate 300 may be textured to reduce reflection of solar energy off the front surface. These process steps may be performed in accordance with known techniques, as shown in FIG. 1.

FIG. 3B shows a tunnel oxide layer 310 being applied to the back surface of the substrate 300. This tunnel oxide layer 310 may be applied using plasma enhanced chemical vapor deposition (PECVD), chemical vapor deposition (CVD), atomic layer deposition (ALD), thermal or dry oxidation. The tunnel oxide layer 310 may be adjusted such that the flow of majority carriers is not adversely affected. In some embodiments, the tunnel oxide layer 310 is between 5 and 30 angstroms, although other thicknesses are also possible. In some embodiments, the tunnel oxide layer 310 is disposed on the entirety of the back surface of the substrate 300.

FIG. 3C shows the application of a mask paste 320 directly to the tunnel oxide layer 310. The mask paste 320 may be soluble in either water or a chemical bath. The mask paste 320 may be a sol/gel type, such as those typically used for high temperature processes. Other MEMS and solar paste, such as those widely used in the industry, may also be employed. The mask paste 320 may have the following properties: ability to endure temperatures up to 600° C. and be soluble for cleaning purposes. The mask paste 320 may be applied onto the tunnel oxide layer 310 so as to form discrete and separate regions. In some embodiments, an inkjet printing method can be used to form desired pattern. In some embodiments, the mask paste 320 may be disposed so as to form two discrete regions, such as those shown in FIG. 2. In other embodiments, the mask paste 320 is disposed in a different configuration, creating at least two separate and discrete regions. Of course, any number of discrete regions is possible, as long as it is greater than one. The mask paste 320 may be between 20 and 200 μm wide. In some embodiments, the mask paste may be about 100 μm wide. In addition, the mask paste 320 may have a height of about 30 μm, although other heights are also possible. In some embodiments, the height of the mask paste 320 is greater than the sum of the heights of the subsequently deposited silicon and metal layers.

FIG. 3D shows the deposition of a silicon layer 330. In some embodiments, the silicon that is deposited may be amorphous silicon (α-Si), nano-crystalline silicon (nc-Si) or micro-crystalline silicon (μc-Si), depending on process conditions. The silicon may be applied using CVD. In some further embodiments, the ambient temperature is maintained below 300° C. during the CVD process to insure that the silicon remains amorphous. Other techniques may also be used to apply the layer of silicon. In another embodiment, polysilicon may be deposited. This may be done by increasing the ambient temperature during the CVD process. In either embodiment, the silicon layer 330 may have a thickness of between about 50 nm and 3 μm. The presence of the mask paste 320 on the tunnel oxide layer 310 prevents silicon from being deposited onto a portion of the tunnel oxide layer 310. Furthermore, since the mask paste 320 is thicker than the silicon layer 330, the mask paste 320 separates the silicon layer 330 into a plurality of discrete regions 335a-c, which are completely separate from one another. Although FIG. 3D shows three separate discrete regions 335a-c, the number of regions is not limited by the disclosure.

After the deposition of the silicon layer 330, dopant is applied to a subset of these discrete regions 335a-c. FIG. 3E shows the implantation of p-type dopant 340, such as boron, into discrete regions 335a, 335c. This may be achieved through the use of a first shadow mask 345, which covers the subset of discrete regions 335b which are not to be implanted. The first shadow mask 345 may be aligned to the underlying mask paste 320, so that the edges of the first shadow mask 345 correspond to the position of the underlying mask paste 320. Thus, a first patterned ion implant may be performed. The p-type dopant 340 may be implanted at an energy of 0.5 to 30 keV. The dose may be selected so as to achieve a sheet resistance (Rₛₕₑₑₜ) of between 20 and 200 ohms/sq. In some embodiments, the dose may be between 8e14 and 1e16 cm². In addition, the implantation parameters, such as dose, species and energy, may be selected to insure that the p-type dopant 340 does not penetrate and damage/attack the tunnel oxide layer 310.

A second implant of n-type dopant 350 is then performed, as shown in FIG. 3F. In this embodiment, a second shadow mask 355 is used to cover the previously doped discrete regions 335a, 335c, so that a second patterned implant may be performed. The second shadow mask 355 may be aligned to the underlying mask paste 320, so that the edges of the second shadow mask 355 correspond to the position of the underlying mask paste 320. An n-type dopant, such as phosphorus, is then implanted into the exposed discrete region 335b. The energy level and dose may be as described above in order to achieve the desired sheet resistance and to insure that n-type dopant 350 does not penetrate and damage/attack the tunnel oxide layer 310.

Thus, FIGS. 3E-3F shows two patterned implants. The first is a patterned implant of a first dopant into a subset of the plurality of discrete regions 335a-c. The second is a patterned implant of a second dopant, having a conductivity opposite the first dopant, into the remainder of the discrete regions 335a-c, not previously doped by the first patterned implant.

However, other embodiments are also possible. For example, FIG. 3E may be replaced with a blanket implant, which implants p-type dopant 340 into all of the discrete regions 335a-c without the use of a shadow mask. The patterned implant performed in FIG. 3F would then need to provide a much greater dose of n-type dopant 350, as it is necessary to counterdope the previously p-type doped discrete region 335b in order to change it into a n-type doped region. The dose of n-type dopant 350 may be such that the resulting dose in the discrete region 335b is greater than 4E15 cm². Similarly, FIG. 3F may be replaced by a blanket implant, which implants n-type dopant 350 into all of the discrete regions 335a-c without the use of a shadow mask. In this embodiment, the dose of p-type dopant implanted in FIG. 3E would be much greater in order to counterdope the previously n-type regions 335a, 335c so as to change them into p-type doped regions. In other words, in some embodiments, a blanket implant of a first dopant is performed, thereby implanting all of the discrete regions 335a-c so that all of the discrete regions are doped with the first dopant. A patterned implant of a second dopant, having a conductivity opposite the first dopant, is performed into a subset of the discrete regions 335a-c. The dose of the second dopant is sufficient to reverse the conductivity of this subset of discrete regions 335a-c.

Furthermore, in all of these embodiments, the sequence in which the p-type dopant 340 and the n-type dopant 350 are implanted may be reversed, such that the n-type dopant 350 may be implanted prior to the implanting of the p-type dopant 340.

In yet another embodiment, the discrete regions 335a-c are doped through the use of diffusion pastes.

After the implants of FIGS. 3E-3F, the device may include an n-type substrate 300, tunnel oxide layer 310, and p-type and n-type discrete regions 335a-c, which are separated by mask paste 320, as shown in FIG. 3G. The p-type doped discrete regions 335a, 335c are the p-type emitter regions, while the n-type doped discrete region 335b is the n-type doped back surface field (BSF) region.

At this point, a thermal process is performed to anneal the silicon layer 330. In some embodiments, this thermal process is an anneal process, which may be conducted at a temperature of less than 600° C. In other embodiments, a rapid thermal process (RTP), laser anneal or e-beam anneal is performed. The thermal process may be performed to insure that the mask paste 320 is not affected. In some embodiments, the thermal process heals damage caused by the implant process and serves to crystallize the silicon. For example, in the case where amorphous silicon (α-Si) is deposited, the thermal process may change this silicon into polysilicon.

After the thermal process, metal is applied to the discrete regions 335a-c, as shown in FIG. 3H. The metal layer 360 may be applied using sputtering, plating or evaporation. Note that because the mask paste 320 is taller than the sum of the silicon layer 330 and the metal layer 360, the regions of the device remain separate. For example, the metal layer 360 may be a metal, where the metal may be aluminum, silver, gold, titanium, nickel, tungsten, or tin. In some embodiments, a seed layer, such as titanium, nickel or titanium tungsten, is first applied to the discrete regions 335a-c. After seeding, a conductive metal, such as copper or aluminum, may be applied. Finally, a cap layer, such as tin or silver, may be applied to prevent erosion or allow soldering. Note that the metal layer 360 may cover the entirety of the bottom surface of the discrete regions 335a-c.

Finally, as shown in FIG. 3I, the mask paste 320 is removed, typically by the application of water or a chemical bath. The resulting solar cell 370 has a bulk n-type substrate 300, having a front surface and a back surface. The tunnel oxide layer 310 is disposed on the back surface of the substrate 300. In addition, a plurality of discrete regions 335a-c is disposed on the back surface of the substrate 300. Each discrete region 335a-c comprises a metal layer 360 disposed on a doped silicon layer 330, which is in turn disposed on the tunnel oxide layer 310. Each of these discrete regions 335a-c is separated from the adjacent discrete regions by a gap, which extends from the metal layer 360 to the tunnel oxide layer 310, which is disposed on the back surface of the substrate 300.

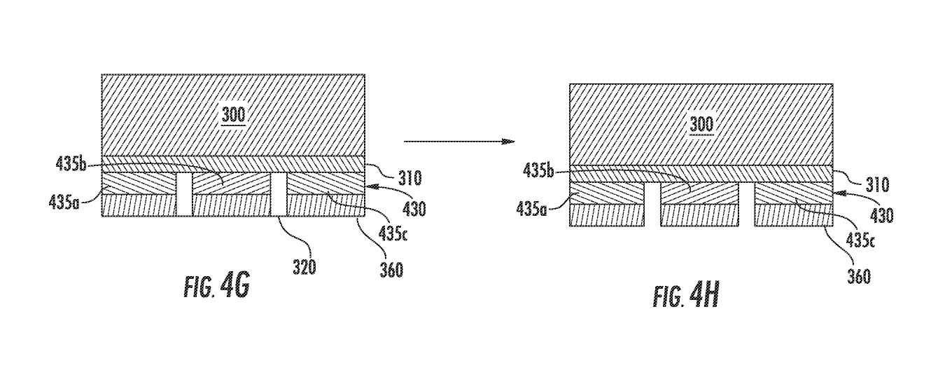

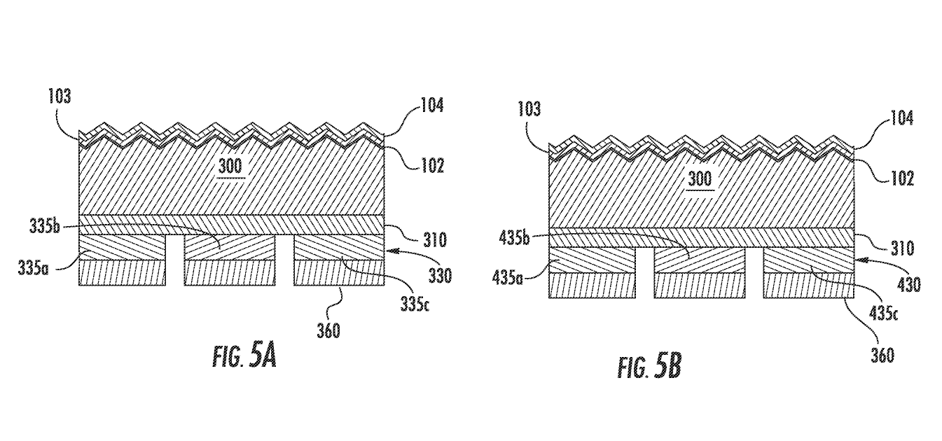

FIG. 5A shows a cross-sectional view of the back contact solar cell made according to the method shown in FIGS. 3A-I. In this figure, the anti-reflective coating (ARC) 104, which may be comprised of an SiNₓ layer, and the passivation layer 103, which may be a SiO₂ layer have been applied to the top (or illuminated) surface. Additionally, a front surface field (FSF) 102 may be created on the top surface. Unlike the traditional back contact solar cell, shown in FIG. 1, the BSF region 335b and the emitter regions 335a,c of FIG. 5A are spaced apart, with no material between them. The gap between the discrete regions 335 extends from the metal layer 360 to the tunnel oxide layer 310.

Furthermore, as seen in FIG. 5A, the metal layer 360 may cover the entirety of the bottom surfaces of the emitter regions 335a,c and the BSF region 335b. This is possible because the emitter regions 335a,c and the BSF region 335b are spaced apart, and there is no risk of the metal layer 360 shorting these two different regions. This eliminates the need to align the metal layer to the different regions.

In contrast, in traditional back contact solar cells, as shown in FIGS. 1 and 2, the metal fingers 220b are not applied on the entirety of the surface of the emitter region 203, and the metal fingers 220a are not applied on the entirety of the surface of the BSF region 204. Rather, the metal fingers 220 only cover a portion of the surfaces of these regions. Accurate alignment of the metal fingers 220 to the emitter regions 203 and BSF regions 204 is required in traditional back contact solar cells to insure separation between the metal fingers of the different regions to avoid shorting.

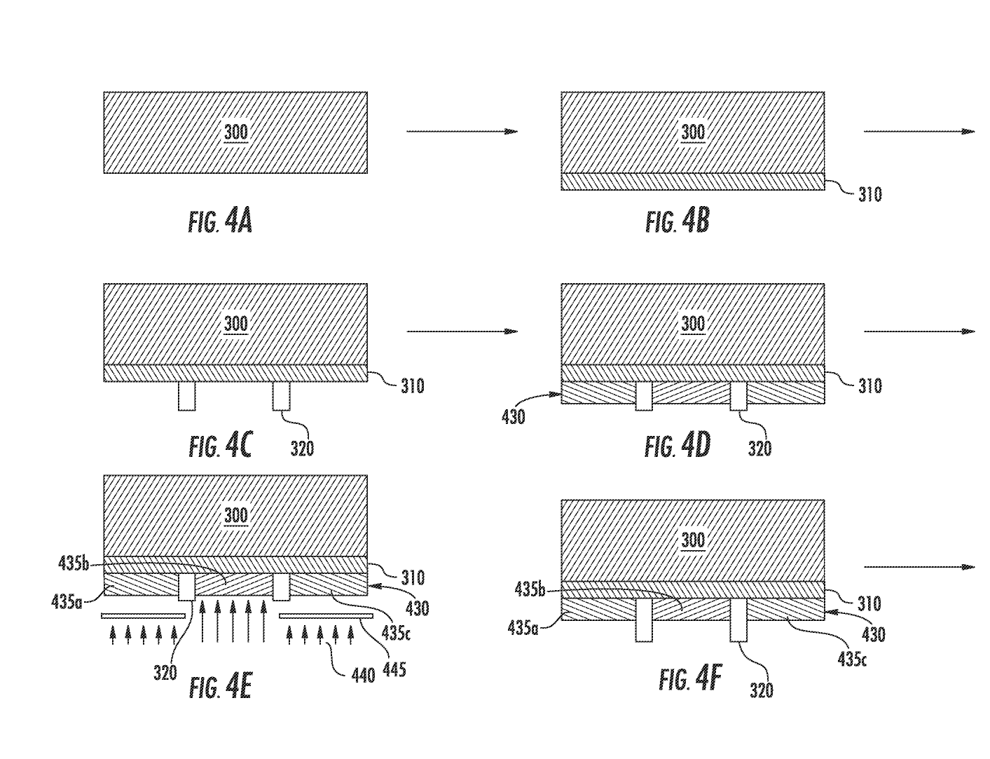

Other processes may be used to create the solar cell shown in FIG. 5A. FIGS. 4A-4H show a second embodiment of the manufacturing process used to create this solar cell. Like components will be given the same reference designators.

The processes shown in FIGS. 4A-4C are identical to those explained in relation to FIGS. 3A-3C, respectively and will not be repeated. FIG. 4D shows a doped silicon layer 430 being deposited on the tunnel oxide layer 310. As described above, the silicon used in this doped silicon layer 430 may be amorphous silicon, deposited using CVD at a temperature of less than 300° C. In other embodiments, polysilicon may be deposited. However, unlike the silicon layer 330 of FIG. 3D, the silicon is co-deposited with a dopant. This co-deposited dopant may be a p-type dopant, such as boron, or may be an n-type dopant, such as phosphorus. Thus, the co-deposition of silicon and a dopant served to form a doped silicon layer 430. Gasses, such as SiH₄ or Si₂H₆ may be used for the deposition of silicon. For doping, another gas, such as PH₃ (for n-type doping) or B₂H₆ (for p-type doping) can be either mixed with the deposition gas or separately used in the process chamber. The resulting layers may be doped amorphous silicon (α-Si), nano-crystalline silicon (nc-Si) or micro-crystalline silicon (μc-Si), depending on process conditions. Since the silicon is already doped during the deposition step, one of the patterned implants described with respect to FIGS. 3E-3F may be eliminated. In this embodiment, the deposition step forms a doped silicon layer 430, with the discrete regions 435a-c already doped. If the dopant is boron, then the emitter regions are formed during the deposition. If the dopant is phosphorus, the BSF fields are formed during the deposition.

In FIG. 4E, a patterned implant is performed, using a shadow mask 445. In one embodiment, n-type dopant 440 is implanted into discrete region 435b. The dose of n-type dopant may be sufficient to counterdope the p-type deposited silicon layer 430, and then to create the n-type region 435b. In some embodiment, an energy of 0.5 to 30 keV is used. The dose may be sufficient so that the sheet resistance of this n-type region 435b is between 20 and 200 ohms/sq. In some embodiments, the dose may be between 8E14 and 1E16 cm⁻². Again, the parameters of the implant may be such that n-type dopant 440 does not penetrate and damage/attack the tunnel oxide layer 310.

In another embodiment, FIG. 4D deposits an n-type dopant with the silicon layer 430. In this embodiment, a p-type dopant is implanted into discrete regions 435a, 435c to counterdope these regions so as to form p-type doped regions. In either embodiment, a dopant of a first conductivity is deposited with the silicon during the deposition step (FIG. 4D). A dopant of a second conductivity, opposite the first conductivity, is then implanted via patterned implant into a subset of the discrete regions 435a-c.

The doped silicon layer 430 is then subjected to a thermal process in FIG. 4F. This thermal process may be as described above with respect to FIG. 3G. Metal layer 360 is then applied in FIG. 4G. This metal layer 360 may be applied using any of the techniques described above with respect to FIG. 3H. Note that the metal layer 360 may cover the entirety of the bottom surface of the discrete regions 435a-c. Finally, the mask paste 320 is removed. This results in the solar cell of FIG. 4H, which is identical in structure to that shown in FIG. 3I.

FIG. 5B shows a completed cross-sectional view of the back contact solar cell made according to the method of FIG. 4A-H. In this figure, the anti-reflective coating (ARC) 104, which may be comprised of an SiNₓ layer, and the passivation layer 103, which may be a SiO₂ layer have been applied to the top (or illuminated) surface. Additionally, a front surface field (FSF) 102 may be created on the top surface. As with FIG. 5A, the emitter regions 435a,c and the BSF region 435b are spaced apart with no material therebetween. The gap between these discrete regions 435 may extend from the metal layer 360 to the tunnel oxide layer 310. In addition, as described above, the metal layer 360 may cover the entireties of the surfaces of the emitter regions 435a,c and BSF region 435b, unlike the configuration shown in FIGS. 1 and 2.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method of creating a back contact solar cell using a substrate, comprising:
depositing a tunnel oxide layer to a surface of said substrate, where said tunnel oxide covers an entirety of said surface;
applying a mask paste to said tunnel oxide layer;
depositing a silicon layer onto said tunnel oxide layer, where said mask paste prevents silicon from being deposited on a portion of said tunnel oxide layer and wherein said mask paste separates the silicon layer into a plurality of discrete regions;
doping each of said plurality of discrete regions, so as to create emitter regions and back surface field regions;
performing a thermal process to anneal said emitter regions and back surface field regions;
applying a metal layer on top of said emitter regions and said back surface field regions after said thermal process; and
removing said mask paste after said applying of said metal layer.

2. The method of claim 1, wherein a thickness of said mask paste is greater than a sum of a thickness of said silicon layer and a thickness of said metal layer.

3. The method of claim 1, wherein depositing said silicon comprises depositing amorphous silicon.

4. The method of claim 1, wherein said doping comprises:
performing a first patterned implant using a first dopant into a subset of said discrete regions; and
performing a second patterned implant using a second dopant, having a conductivity opposite said first dopant, into a remainder of said discrete regions.

5. The method of claim 1, wherein said doping comprises:
performing a blanket implant using a first dopant into all of said discrete regions; and
performing a patterned implant using a second dopant, having a conductivity opposite said first dopant, into a subset of said discrete regions.

6. The method of claim 1, wherein said metal layer is applied using sputtering.

7. The method of claim 1, wherein said thermal process creates polysilicon.

8. A method of creating a back contact solar cell using a substrate, comprising:
depositing a tunnel oxide layer to a surface of said substrate, where said tunnel oxide covers an entirety of said surface;
applying a mask paste to said tunnel oxide layer;
depositing silicon and a first dopant onto said tunnel oxide layer to form a doped silicon layer, where said mask paste prevents silicon and said first dopant from being deposited on a portion of said tunnel oxide layer and wherein said mask paste separates the doped silicon layer into a plurality of discrete regions, wherein each of said discrete regions is already doped;
doping a subset of said plurality of discrete regions, with a second dopant, having a conductivity opposite said first dopant, sufficient to change the conductivity of said subset, to create emitter regions and back surface field regions;
performing a thermal process to anneal said emitter regions and back surface field regions;
applying a metal layer on top of said emitter regions and said back surface field regions after said thermal process; and
removing said mask paste after said applying of said metal layer.

9. The method of claim 8, wherein a thickness of said mask paste is greater than a sum of a thickness of said doped silicon layer and a thickness of said metal layer.

10. The method of claim 8, wherein depositing said silicon comprises depositing amorphous silicon.

11. The method of claim 8, wherein said metal layer is applied using sputtering.

12. The method of claim 8, wherein said thermal process creates polysilicon.

13. A back contact solar cell, comprising:
a substrate having a front surface and a back surface;
a tunnel oxide layer disposed on said back surface; and
a plurality of discrete regions disposed on said tunnel oxide layer, each discrete region comprising:
a doped silicon layer disposed on said tunnel oxide layer; and
a metal layer disposed on said doped silicon layer;
wherein each of said discrete regions is separated from an adjacent discrete region by a gap.

14. The back contact solar cell of claim 13, wherein said gap extends from said metal layer to said tunnel oxide layer.

15. The back contact solar cell of claim 13, wherein said metal layer covers an entirety of said doped silicon layer.

16. The back contact solar cell of claim 13, further comprising a passivation layer and an anti-reflective layer disposed on said front surface.

17. The back contact solar cell of claim 13, wherein a first subset of said plurality of discrete regions comprises p-type doped emitter regions and a second subset of said plurality of discrete regions comprises n-type doped back surface field regions.
